(19) United States
(12) Patent Application Publication
(10) Pub. No.: US 2014/0063022 A1
(43) Pub. Date: Mar. 6, 2014

(54) ELECTROMECHANICAL SYSTEMS DEVICE

(71) Applicants: Edward K. Chan, San Diego, CA (US); Bing Wen, Poway, CA (US); Cheonhong Kim, San Diego, CA (US); John H. Hong, San Diego, CA (US)

(72) Inventors: Edward K. Chan, San Diego, CA (US); Bing Wen, Poway, CA (US); Cheonhong Kim, San Diego, CA (US); John H. Hong, San Diego, CA (US)

(73) Assignee: Qualcomm Mems Technologies, Inc., San Diego, CA (US)

(21) Appl. No.: 13/601,226

(22) Filed: Aug. 31, 2012

(51) Int. Cl. G02B 26/00; G06T 1/00; H01L 33/08

(52) U.S. Cl. 345/501; 359/290; 438/34; 257/E33.053

(57) ABSTRACT

This disclosure provides systems, methods and apparatus for electromechanical systems devices including one or more storage capacitors. In one aspect, a device includes a substrate structure, a movable element configured to move relative to the substrate structure, and at least one switch. The movable element includes a first conductive layer and a second conductive layer that form a storage capacitor. The switch is configured to control a flow of charge between a source and the storage capacitor.

### TECHNICAL FIELD

This disclosure relates to electromechanical systems.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

In an EMS device, the reflective membrane can be moved between an actuated position and a relaxed position by application of a voltage between an electrode coupled to the reflective membrane and a stationary electrode. However, charge leakage from the movable reflective membrane can impact the performance of the EMS device. For example, the refresh rate of the device can be affected by charge leakage. Accordingly, there is a need for reducing the impact of charge leakage and for improving the operational performance of EMS devices.

### SUMMARY

The systems, methods and devices of this disclosure each have several innovative aspects, no single one of which is solely responsible for the desirable attributes disclosed herein.

One innovative aspect of the subject matter described in this disclosure can be implemented in a device including a substrate structure, a movable element, and at least one switch. The movable element includes a first conductive layer and a second conductive layer, and the movable element is configured to move in a direction generally perpendicular to the substrate. The first and second conductive layers form a storage capacitor. The at least one switch is configured to control a flow of charge between a source and the storage capacitor.

In some implementations, the device can be configured such that the storage capacitor is electrically coupled to the movable element and provides voltage to the movable element at least when the movable element is actuated. In some implementations, the device can include an optical stack disposed between the movable element and the substrate structure. The optical stack can include a partially reflective and partially transmissive layer. The optical stack and the movable element can form an interferometric modulator (IMOD) display element.

In some implementations, the at least one switch can include a thin-film transistor. The movable element can include a dielectric layer disposed between the first conductive layer and the second conductive layer, for example, silicon oxy-nitride having a thickness dimension between 20 nm and 4000 nm.

Another innovative aspect of the subject matter described in this disclosure can be implemented in a method of forming a device. The method includes forming a substrate structure, forming a movable element, and forming at least one switch. The movable element is configured to move in a direction generally perpendicular to the substrate structure and includes a first conductive layer and a second conductive layer, which form a storage capacitor. The switch is configured to control a flow of charge between a source and the storage capacitor.

In some implementations, the method can include forming an optical stack, the optical stack being disposed between the movable element and the substrate structure. Forming the at least one switch can include forming a thin-film transistor, in some aspects.

Another innovative aspect of the subject matter described in this disclosure can be implemented in a device including an electromechanical system including a substrate structure and a display element including a movable means for storing charge and for reflecting light. The light reflecting charge storing means is configured to be driven in a direction generally perpendicular to the substrate structure to at least a first actuated position and a relaxed position. The light reflecting charge storing means is configured to provide voltage to at least one conductive layer of the movable means while the movable means is being actuated. The device also includes a means for controlling a flow of charge between a source and the storage capacitor.

In some implementations, the movable means for storing charge and for reflecting light can include a first conductive layer, a second conductive layer, and a dielectric layer between the first conductive layer and the second conductive layer. The first and second conductive layers and the dielectric layer can form a movable storage capacitor. In some implementations, the charge controlling means can include at least one switch, for example, a thin-film transistor.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIG. 3 is a graph illustrating movable reflective layer position versus applied voltage for an IMOD display element.

FIG. 4 is a table illustrating various states of an IMOD display element when various common and segment voltages are applied.

FIGS. 5A-5E are cross-sectional illustrations of varying implementations of IMOD display elements.

FIG. 6 is a flow diagram illustrating a manufacturing process for an IMOD display or display element.

FIGS. 7A-7E are cross-sectional illustrations of various stages in a process of making an IMOD display or display element.

FIG. 8 shows a circuit diagram for one example of an active-matrix IMOD array.

FIG. 9 shows a schematic plan view of one example of an active-matrix array of display elements.

FIGS. 10A-10P show examples of cross-sectional schematic illustrations of various stages in a method of making the active-matrix array of FIG. 9 taken along the line 10-10.

FIG. 11 shows an example of a flow diagram illustrating a method of forming a device.

FIG. 12A shows an example of voltage over time for movable elements including a storage capacitor and for movable elements without a storage capacitor.

FIG. 12B shows an example of position over time for the movable elements of FIG. 12A with the position measured relative to a stationary electrode.

FIGS. 13A and 13B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

In certain implementations, active-matrix EMS devices include at least one storage capacitor. As used herein, the term “active-matrix” can refer to an EMS device in which the each pixel, sub-pixel, or element of the device is individually controlled (or driven) using an active switch, such as a thin-film transistor (TFT). In other words, an actuation state of each pixel, sub-pixel, or element can be individually controlled using an active switch. The EMS device can include an optical stack disposed over a substrate and a movable reflective membrane (also referred to herein as a mechanical layer or movable element) positioned over the optical stack to define a gap. The optical stack can include a stationary electrode and one or more dielectric layers. The movable element can include an electrode and is movable within the gap in response to a voltage applied between the movable element and the stationary electrode. For example, one or more conductive portions of the movable element can form the movable electrode. The movable electrode can include a movable portion of a conductive layer, the conductive layer also having a non-movable portion, electrically coupling the movable element to another non-movable electrical component. A voltage difference between the movable electrode and the stationary electrode can be used to generate an electrostatic force that can move the movable element. In some implementations, a movable element includes a first conductive layer that is offset from a second conductive layer. In such implementations, the first or second conductive layers can form the movable electrode.

In some implementations, to improve electrical and/or optical performance, the EMS device can include one or more storage capacitors and an active switch formed at least partially in an optically non-active region of the device. Such non-active regions include regions of a display element in the device that are not used to provide light, for example, regions that are masked from receiving light and regions that are behind reflective structures. An EMS device that includes an integrated storage capacitor can increase a capacitance associated with a pixel, thereby reducing pixel leakage, reducing drive voltage and/or improving an image refresh of the display. Such storage capacitors can include a first plate or layer, a second plate or layer, and a spacer layer which can be, for example, a dielectric layer, disposed between the first and second layers. In some implementations, the movable element includes the first and second layers and the spacer layer of the storage capacitor. In some implementations, one of the first and second conductive layers of the movable layer can form the movable electrode and one terminal of the storage capacitor, and the other of the first and second conductive layers can form a second terminal of the storage capacitor which can be electrically coupled to a switch. Using layers of a movable element to form the storage capacitor can improve the integration of the pixel array by utilizing already existing components of the EMS device to perform multiple optical and/or electrical functions, thereby reducing a pixel array footprint. In some implementations, an active switch is also formed over an optical mask structure to further enhance display integration.

Particular implementations of the subject matter described in this disclosure can be implemented to realize one or more of the following potential advantages. For example, some implementations described in this disclosure reduce the drive voltage of a display and/or reduce the impacts of pixel current leakage relative to certain other configurations of displays, such as other active-matrix displays omitting a storage capacitor. Furthermore, some implementations improve an image refresh rate (i.e., increasing the length of time before an image on the display must be refreshed before it begins to degrade) of a display compared to active-matrix displays without a storage capacitor. That is, by reducing leakage, the storage capacitor may enable a display element to maintain the color or image data written to the display element without requiring refresh. Moreover, some implementations improve integration of components of a display, thereby allowing the display to be fabricated using a smaller die area compared to designs where a storage capacitor is added as a separate component that does not use any of the existing layers for its structure. Additionally, some implementations can be used to increase a capacitance associated with pixels of a display. Some implementations can be used to reduce fabrication complexity by using layers already used in forming pixels to form a storage capacitor. Some implementations can be used to reduce the power consumption of an array and/or otherwise improve the performance of the array. Further, by putting a storage capacitor formed as part of a movable element in series with a drive voltage, an electrical gap between the movable element and a stationary electrode can be extended beyond the optical or physical gap between the movable electrode and the stationary electrode. Because the stable range of movement an EMS device may be limited to one-third of the electrical gap, in some implementations, the stable range of movement through the optical or physical gap can be extended. In this way, implementations described herein can improve the effects of charge leakage on the refresh rate, power consumption, and color variation of a display device without negatively impacting the device's fill factor as compared to other devices that do not include a storage capacitor to offset charge leakage effects, or to other devices that include a discrete storage capacitor that reduces the pixel's active area.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

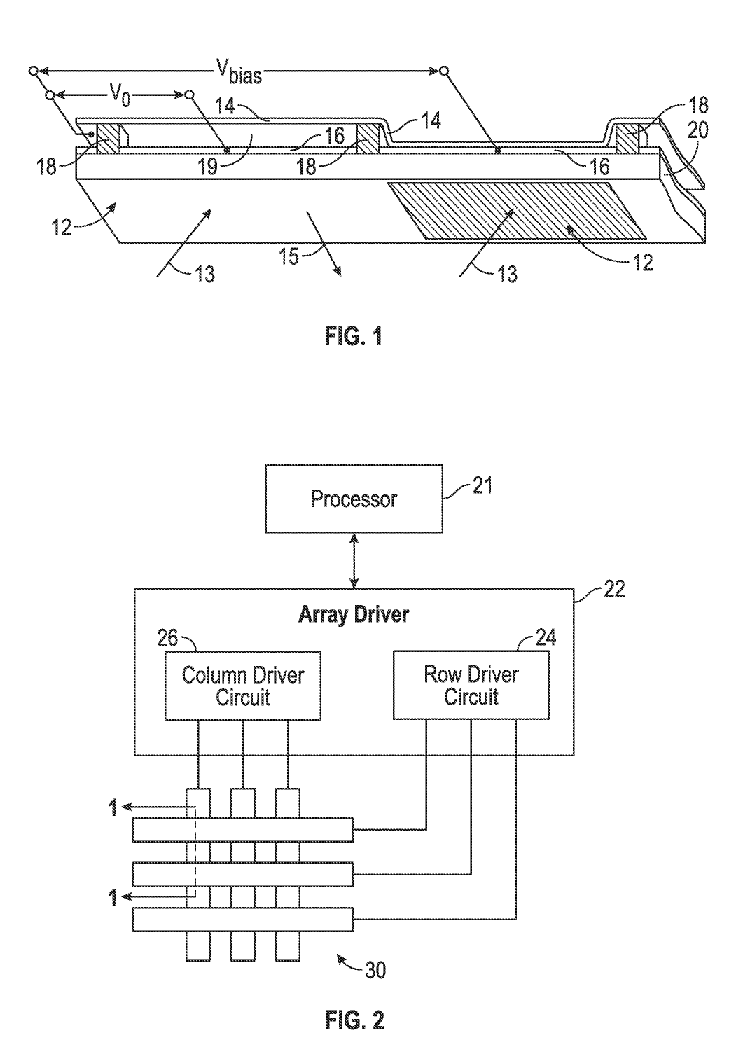

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

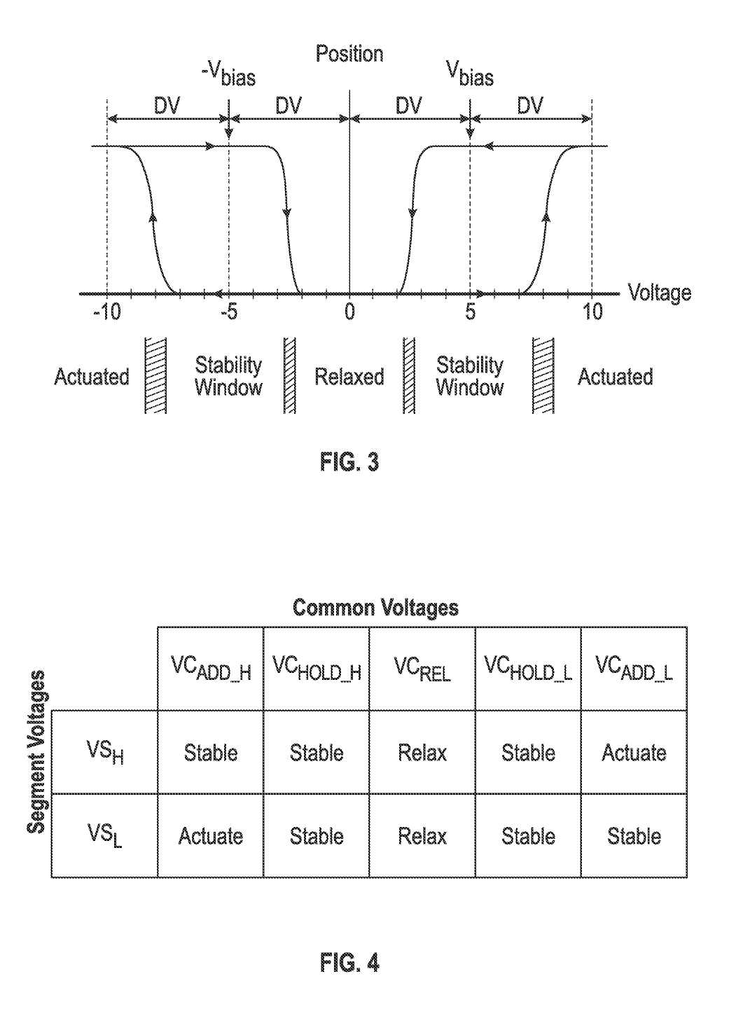

FIG. 3 is a graph illustrating movable reflective layer position versus applied voltage for an IMOD display element. For IMODs, the row/column (i.e., common/segment) write procedure may take advantage of a hysteresis property of the display elements as illustrated in FIG. 3. An IMOD display element may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3-7 volts, in the example of FIG. 3, exists where there is a window of applied voltage within which the element is stable in either the relaxed or actuated state. This is referred to herein as the “hysteresis window” or “stability window.” For a display array 30 having the hysteresis characteristics of FIG. 3, the row/column write procedure can be designed to address one or more rows at a time. Thus, in this example, during the addressing of a given row, display elements that are to be actuated in the addressed row can be exposed to a voltage difference of about 10 volts, and display elements that are to be relaxed can be exposed to a voltage difference of near zero volts. After addressing, the display elements can be exposed to a steady state or bias voltage difference of approximately 5 volts in this example, such that they remain in the previously strobed, or written, state. In this example, after being addressed, each display element sees a potential difference within the “stability window” of about 3-7 volts. This hysteresis property feature enables the IMOD display element design to remain stable in either an actuated or relaxed pre-existing state under the same applied voltage conditions. Since each IMOD display element, whether in the actuated or relaxed state, can serve as a capacitor formed by the fixed and moving reflective layers, this stable state can be held at a steady voltage within the hysteresis window without substantially consuming or losing power. Moreover, essentially little or no current flows into the display element if the applied voltage potential remains substantially fixed.

In some implementations, a frame of an image may be created by applying data signals in the form of “segment” voltages along the set of column electrodes, in accordance with the desired change (if any) to the state of the display elements in a given row. Each row of the array can be addressed in turn, such that the frame is written one row at a time. To write the desired data to the display elements in a first row, segment voltages corresponding to the desired state of the display elements in the first row can be applied on the column electrodes, and a first row pulse in the form of a specific “common” voltage or signal can be applied to the first row electrode. The set of segment voltages can then be changed to correspond to the desired change (if any) to the state of the display elements in the second row, and a second common voltage can be applied to the second row electrode. In some implementations, the display elements in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each display element (that is, the potential difference across each display element or pixel) determines the resulting state of each display element. FIG. 4 is a table illustrating various states of an IMOD display element when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

As illustrated in FIG. 4, when a release voltage VC_{REL} is applied along a common line, all IMOD display elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator display elements or pixels (alternatively referred to as a display element or pixel voltage) can be within the relaxation window (see FIG. 3, also referred to as a release window) both when the high segment voltage VS_{H} and the low segment voltage VS_{L} are applied along the corresponding segment line for that display element.

When a hold voltage is applied on a common line, such as a high hold voltage VC_{HOLD}_{_{—}}_{H} or a low hold voltage VC_{HOLD}_{_{—}}_{L}, the state of the IMOD display element along that common line will remain constant. For example, a relaxed IMOD display element will remain in a relaxed position, and an actuated IMOD display element will remain in an actuated position. The hold voltages can be selected such that the display element voltage will remain within a stability window both when the high segment voltage VS_{H} and the low segment voltage VS_{L} are applied along the corresponding segment line. Thus, the segment voltage swing in this example is the difference between the high VS_{H} and low segment voltage VS_{L}, and is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that common line by application of segment voltages along the respective segment lines. The segment voltages may be selected such that actuation is dependent upon the segment voltage applied. When an addressing voltage is applied along a common line, application of one segment voltage will result in a display element voltage within a stability window, causing the display element to remain unactuated. In contrast, application of the other segment voltage will result in a display element voltage beyond the stability window, resulting in actuation of the display element. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having substantially no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation that could occur after repeated write operations of a single polarity.

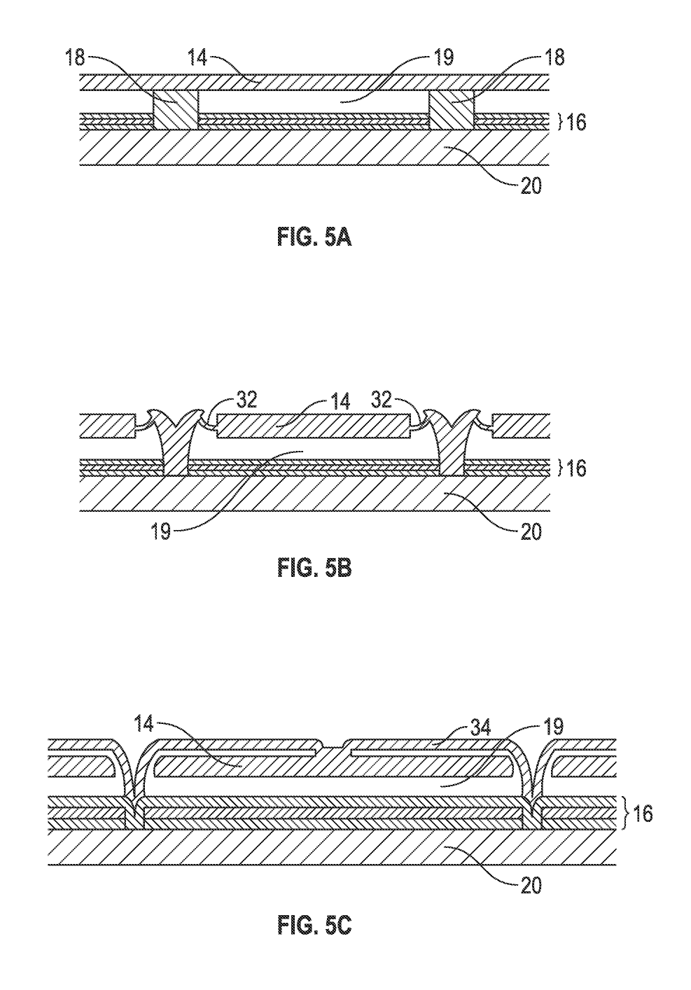

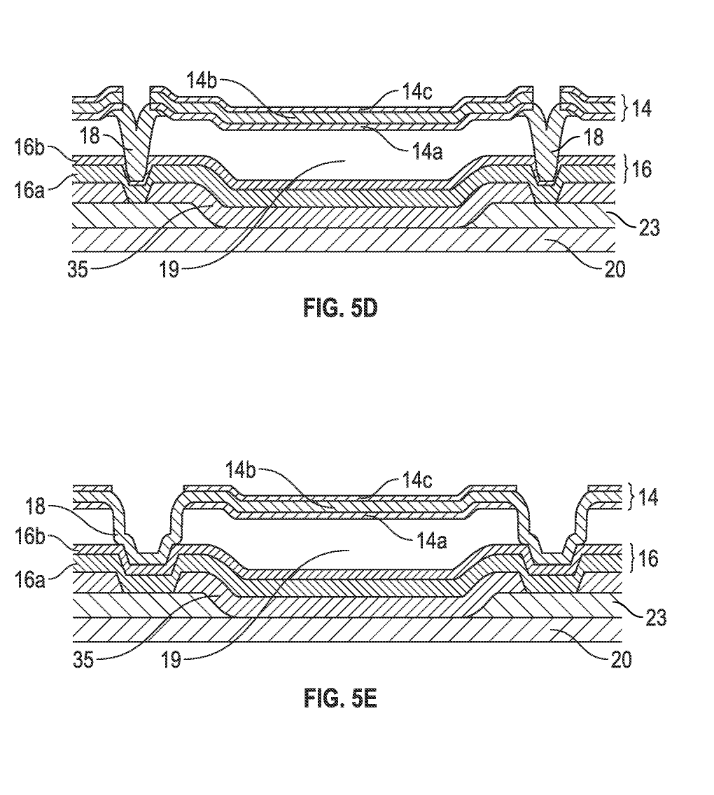

The details of the structure of IMOD displays and display elements may vary widely. FIGS. 5A-5E are cross-sectional illustrations of varying implementations of IMOD display elements. FIG. 5A is a cross-sectional illustration of an IMOD display element, where a strip of metal material is deposited on supports 18 extending generally orthogonally from the substrate 20 forming the movable reflective layer 14. In FIG. 5B, the movable reflective layer 14 of each IMOD display element is generally square or rectangular in shape and attached to supports at or near the corners, on tethers 32. In FIG. 5C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as implementations of “integrated” supports or support posts 18. The implementation shown in FIG. 5C has additional benefits deriving from the decoupling of the optical functions of the movable reflective layer 14 from its mechanical functions, the latter of which are carried out by the deformable layer 34. This decoupling allows the structural design and materials used for the movable reflective layer 14 and those used for the deformable layer 34 to be optimized independently of one another.

FIG. 5D is another cross-sectional illustration of an IMOD display element, where the movable reflective layer 14 includes a reflective sub-layer 14a. The movable reflective layer 14 rests on a support structure, such as support posts 18. The support posts 18 provide separation of the movable reflective layer 14 from the lower stationary electrode, which can be part of the optical stack 16 in the illustrated IMOD display element. For example, a gap 19 is formed between the movable reflective layer 14 and the optical stack 16, when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 5D, some implementations also can include a black mask structure 23, or dark film layers. The black mask structure 23 can be formed in optically inactive regions (such as between display elements or under the support posts 18) to absorb ambient or stray light. The black mask structure 23 also can improve the optical properties of a display device by inhibiting light from being reflected from or transmitted through inactive portions of the display, thereby increasing the contrast ratio. Additionally, at least some portions of the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. In some implementations, the black mask structure 23 can be an etalon or interferometric stack structure. For example, in some implementations, the interferometric stack black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, tetrafluoromethane (or carbon tetrafluoride, CF₄) and/or oxygen (O₂) for the MoCr and SiO₂ layers and chlorine (Cl₂) and/or boron trichloride (BCl₃) for the aluminum alloy layer. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate electrodes (or conductors) in the optical stack 16 (such as the absorber layer 16a) from the conductive layers in the black mask structure 23.

FIG. 5E is another cross-sectional illustration of an IMOD display element, where the movable reflective layer 14 is self-supporting. While FIG. 5D illustrates support posts 18 that are structurally and/or materially distinct from the movable reflective layer 14, the implementation of FIG. 5E includes support posts that are integrated with the movable reflective layer 14. In such an implementation, the movable reflective layer 14 contacts the underlying optical stack 16 at multiple locations, and the curvature of the movable reflective layer 14 provides sufficient support that the movable reflective layer 14 returns to the unactuated position of FIG. 5E when the voltage across the IMOD display element is insufficient to cause actuation. In this way, the portion of the movable reflective layer 14 that curves or bends down to contact the substrate or optical stack 16 may be considered an “integrated” support post. One implementation of the optical stack 16, which may contain a plurality of several different layers, is shown here for clarity including an optical absorber 16a, and a dielectric 16b. In some implementations, the optical absorber 16a may serve both as a stationary electrode and as a partially reflective layer. In some implementations, the optical absorber 16a can be an order of magnitude thinner than the movable reflective layer 14. In some implementations, the optical absorber 16a is thinner than the reflective sub-layer 14a.

In implementations such as those shown in FIGS. 5A-5E, the IMOD display elements form a part of a direct-view device, in which images can be viewed from the front side of the transparent substrate 20, which in this example is the side opposite to that upon which the IMOD display elements are formed. In these implementations, the back portions of the device (that is, any portion of the display device behind the movable reflective layer 14, including, for example, the deformable layer 34 illustrated in FIG. 5C) can be configured and operated upon without impacting or negatively affecting the image quality of the display device, because the reflective layer 14 optically shields those portions of the device. For example, in some implementations a bus structure (not illustrated) can be included behind the movable reflective layer 14 that provides the ability to separate the optical properties of the modulator from the electromechanical properties of the modulator, such as voltage addressing and the movements that result from such addressing.

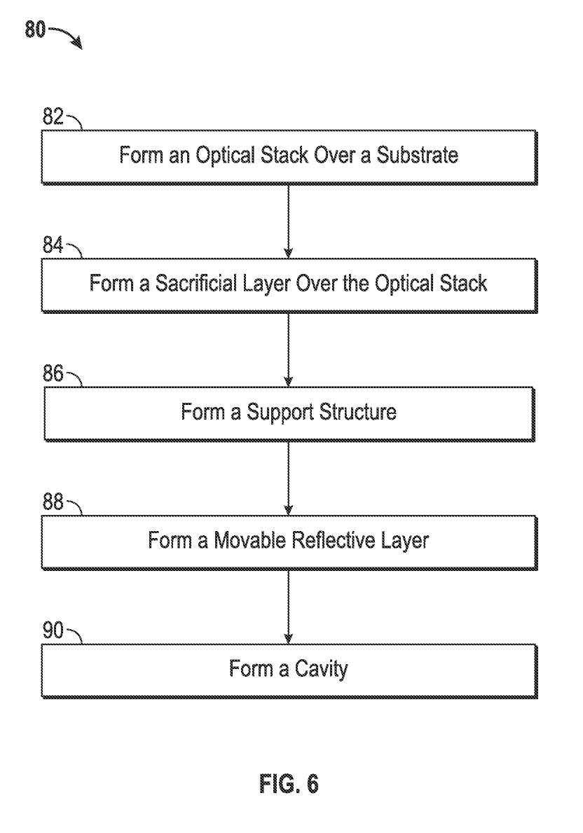

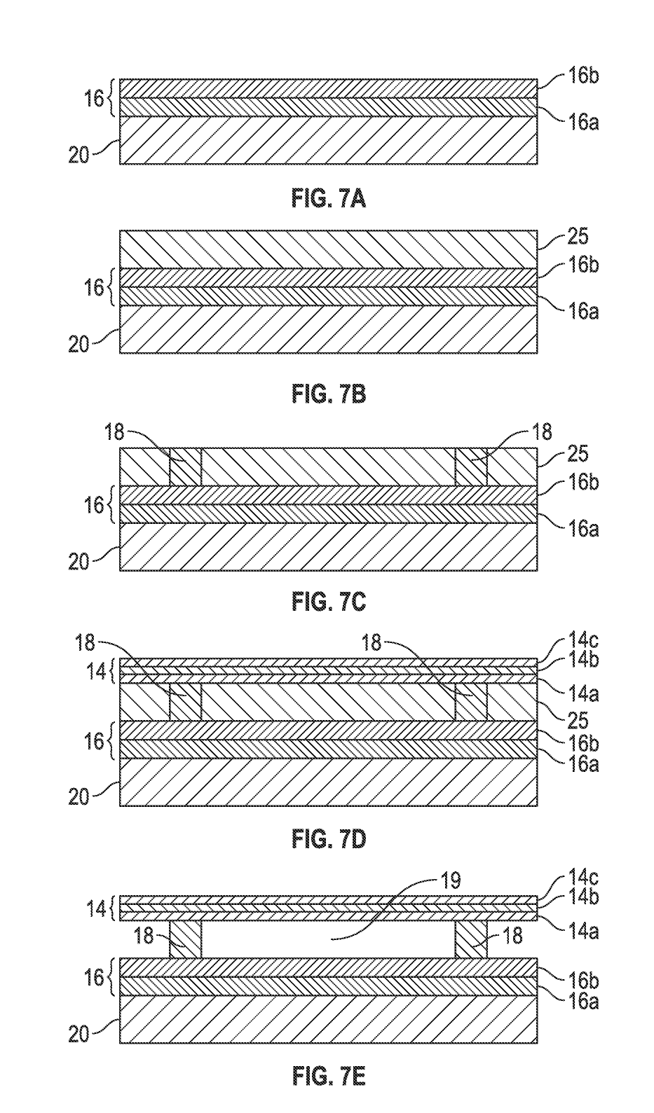

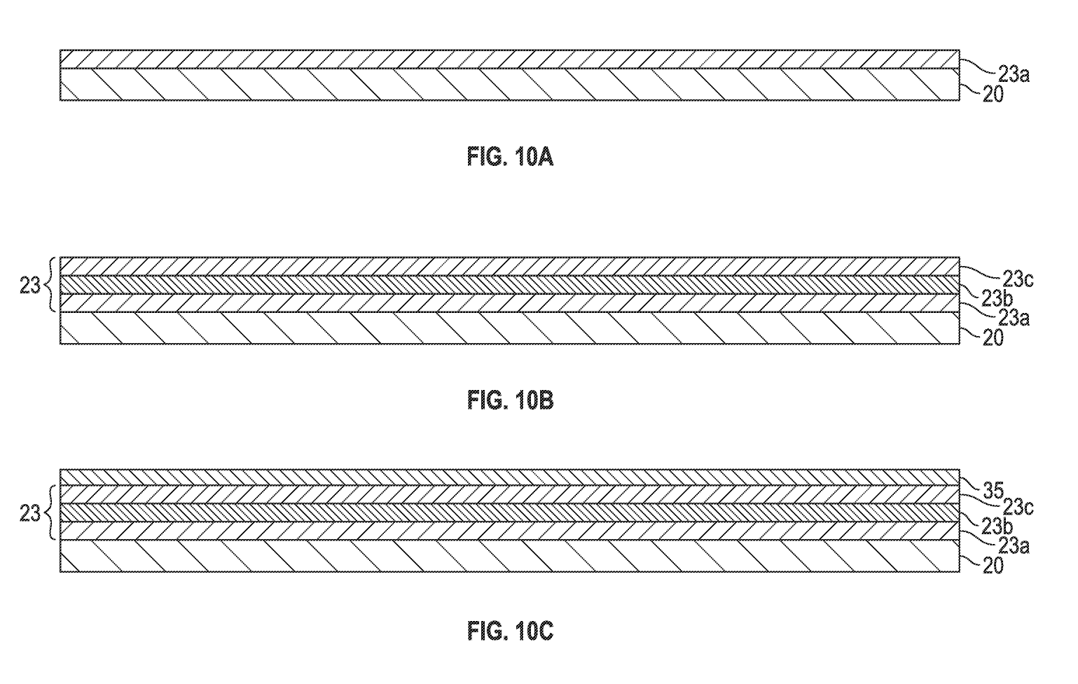

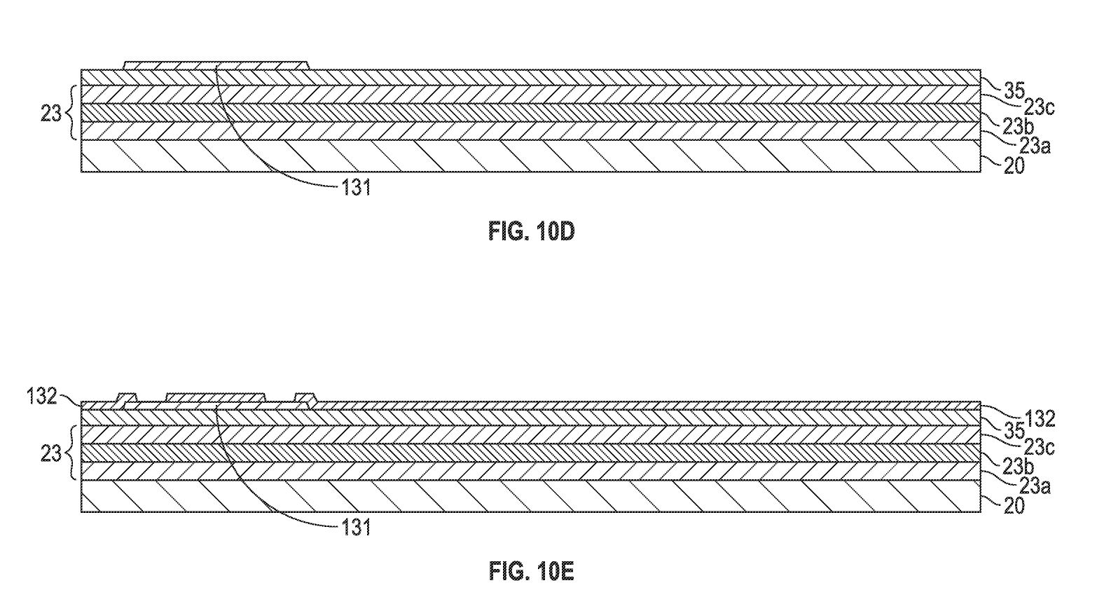

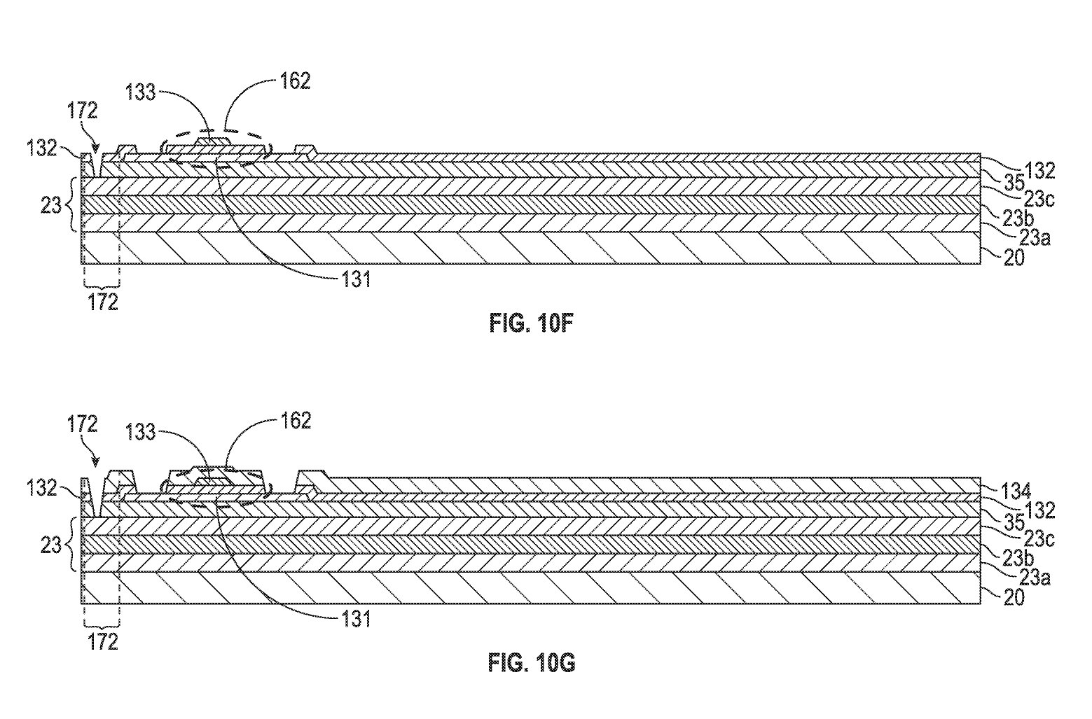

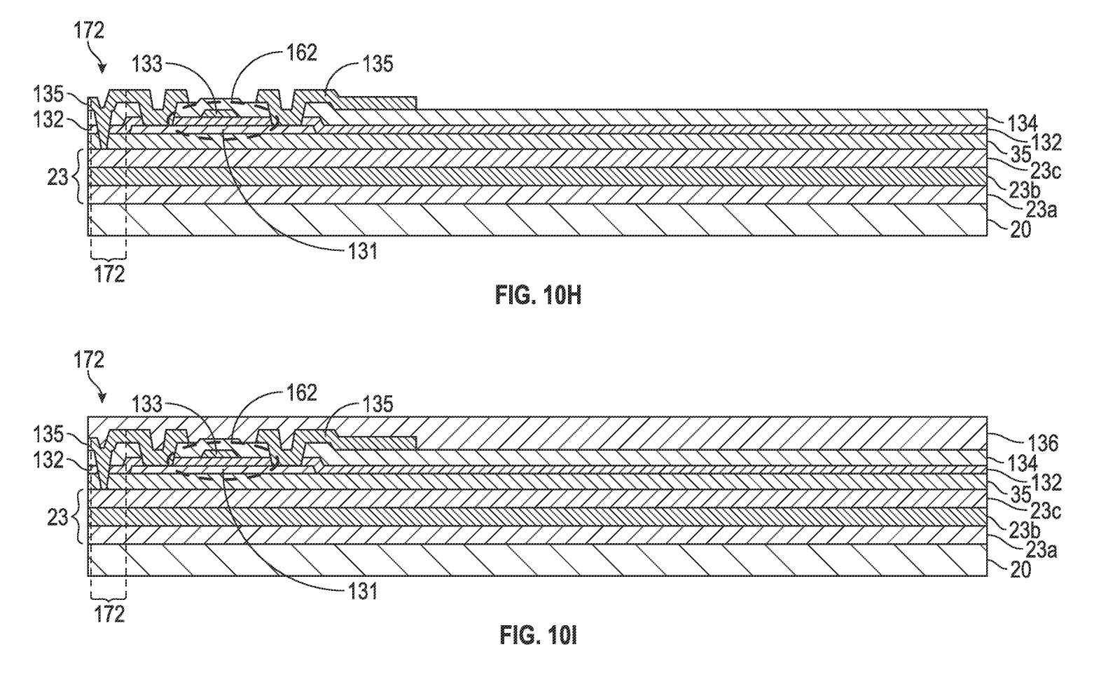

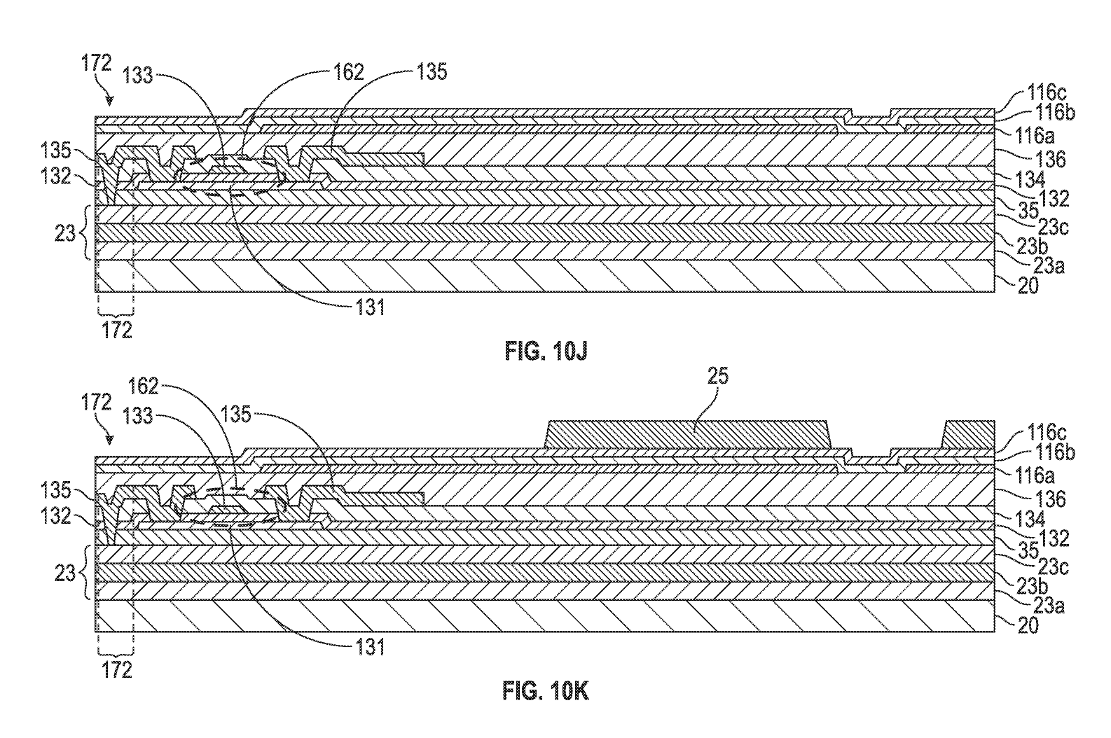

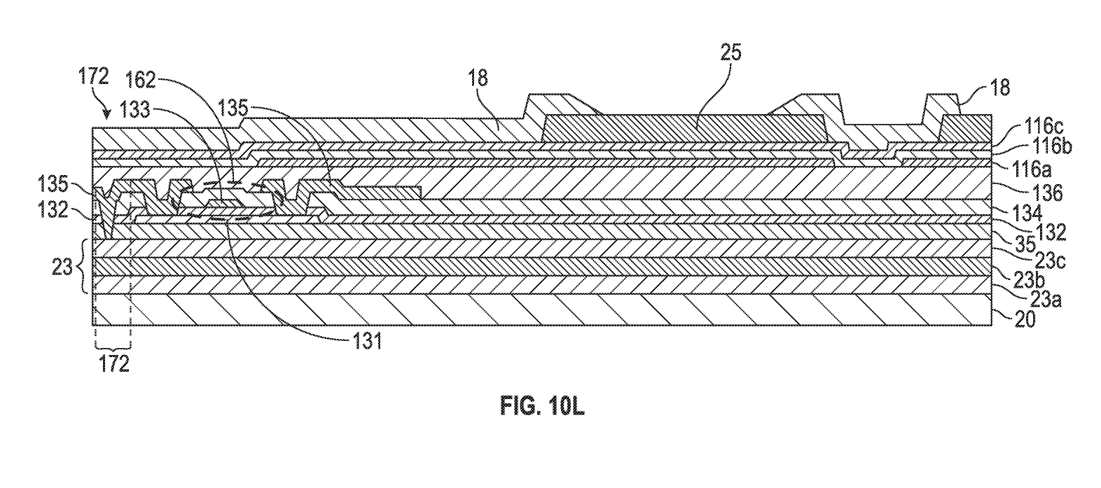

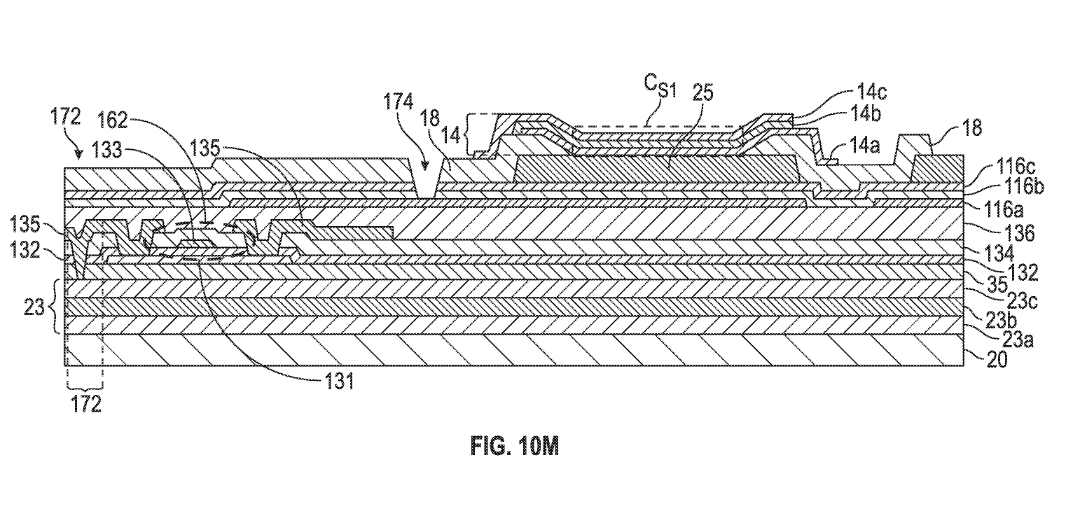

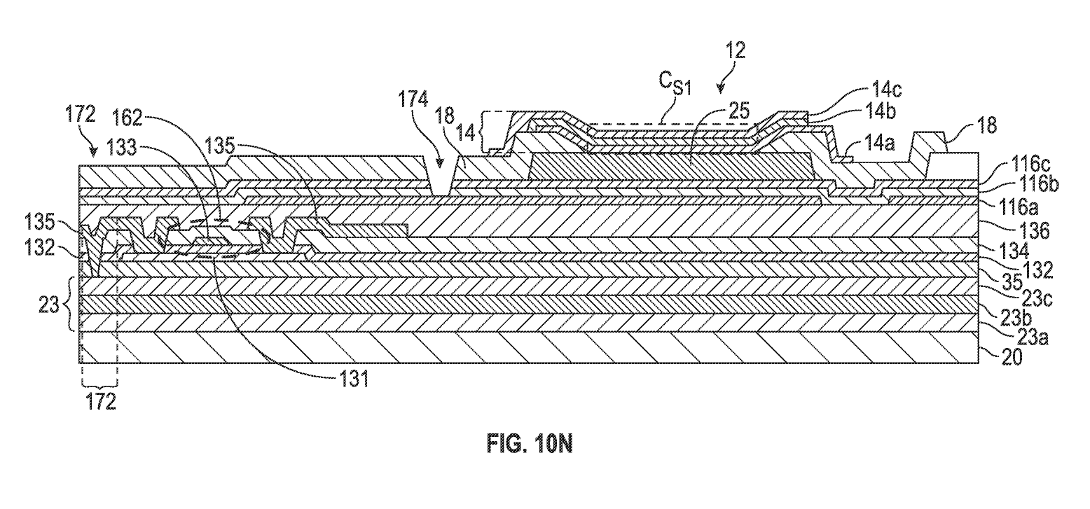

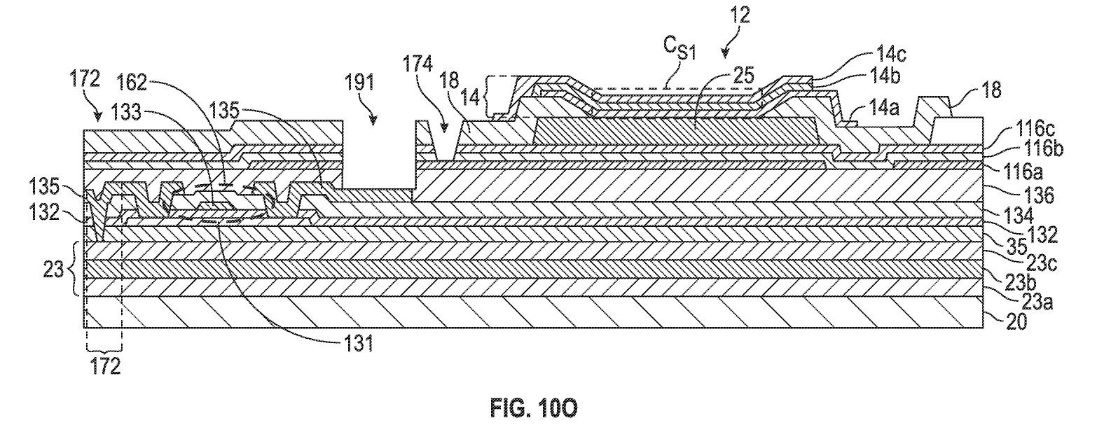

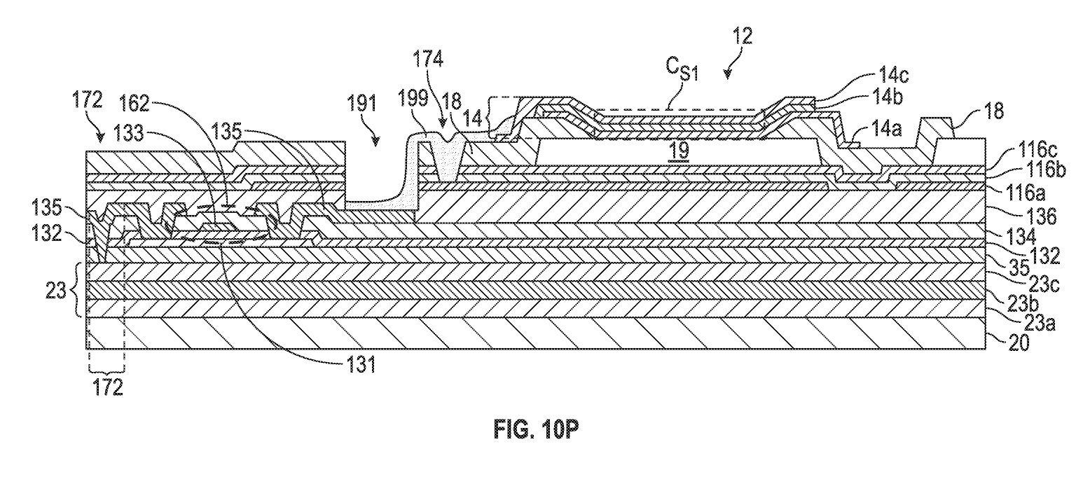

FIG. 6 is a flow diagram illustrating a manufacturing process 80 for an IMOD display or display element. FIGS. 7A-7E are cross-sectional illustrations of various stages in the manufacturing process 80 for making an IMOD display or display element. In some implementations, the manufacturing process 80 can be implemented to manufacture one or more EMS devices, such as IMOD displays or display elements. The manufacture of such an EMS device also can include other blocks not shown in FIG. 6. For example, the process 80 can be utilized to manufacture a display element with an associated storage capacitor as discussed below with reference to FIGS. 10A-10P. The process 80 begins at block 82 with the formation of the optical stack 16 over the substrate 20. FIG. 7A illustrates such an optical stack 16 formed over the substrate 20. The substrate 20 may be a transparent substrate such as glass or plastic such as the materials discussed above with respect to FIG. 1. The substrate 20 may be flexible or relatively stiff and unbending, and may have been subjected to prior preparation processes, such as cleaning, to facilitate efficient formation of the optical stack 16. As discussed above, the optical stack 16 can be electrically conductive, partially transparent, partially reflective, and partially absorptive, and may be fabricated, for example, by depositing one or more layers having the desired properties onto the transparent substrate 20.

In FIG. 7A, the optical stack 16 includes a multilayer structure having sub-layers 16a and 16b, although more or fewer sub-layers may be included in some other implementations. In some implementations, one of the sub-layers 16a and 16b can be configured with both optically absorptive and electrically conductive properties, such as the combined conductor/absorber sub-layer 16a. In some implementations, one of the sub-layers 16a and 16b can include molybdenum-chromium (molychrome or MoCr), or other materials with a suitable complex refractive index. Additionally, one or more of the sub-layers 16a and 16b can be patterned into parallel strips, and may form row electrodes in a display device. Such patterning can be performed by a masking and etching process or another suitable process known in the art. In some implementations, one of the sub-layers 16a and 16b can be an insulating or dielectric layer, such as an upper sub-layer 16b that is deposited over one or more underlying metal and/or oxide layers (such as one or more reflective and/or conductive layers). In addition, the optical stack 16 can be patterned into individual and parallel strips that form the rows of the display. In some implementations, at least one of the sub-layers of the optical stack, such as the optically absorptive layer, may be quite thin (e.g., relative to other layers depicted in this disclosure), even though the sub-layers 16a and 16b are shown somewhat thick in FIGS. 7A-7E.

The process 80 continues at block 84 with the formation of a sacrificial layer 25 over the optical stack 16. Because the sacrificial layer 25 is later removed (see block 90) to form the cavity 19, the sacrificial layer 25 is not shown in the resulting IMOD display elements. FIG. 7B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIG. 7E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as a support post 18. The formation of the support post 18 may include patterning the sacrificial layer 25 to form a support structure aperture, then depositing a material (such as a polymer or an inorganic material, like silicon oxide) into the aperture to form the support post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the support post 18 contacts the substrate 20. Alternatively, as depicted in FIG. 7C, the aperture formed in the sacrificial layer 25 can extend through the sacrificial layer 25, but not through the optical stack 16. For example, FIG. 7E illustrates the lower ends of the support posts 18 in contact with an upper surface of the optical stack 16. The support post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 7C, but also can extend at least partially over a portion of the sacrificial layer 25. As noted above, the patterning of the sacrificial layer 25 and/or the support posts 18 can be performed by a masking and etching process, but also may be performed by alternative patterning methods.

The process 80 continues at block 88 with the formation of a movable reflective layer or membrane such as the movable reflective layer 14 illustrated in FIG. 7D. The movable reflective layer 14 may be formed by employing one or more deposition steps, including, for example, reflective layer (such as aluminum, aluminum alloy, or other reflective materials) deposition, along with one or more patterning, masking and/or etching steps. The movable reflective layer 14 can be patterned into individual and parallel strips that form, for example, the columns of the display. The movable reflective layer 14 can be electrically conductive, and referred to as an electrically conductive layer. In some implementations, the movable reflective layer 14 may include a plurality of sub-layers 14a, 14b and 14c as shown in FIG. 7D. In some implementations, one or more of the sub-layers, such as sub-layers 14a and 14c, may include highly reflective sub-layers selected for their optical properties, and another sub-layer 14b may include a mechanical sub-layer selected for its mechanical properties. In some implementations, the mechanical sub-layer may include a dielectric material. Since the sacrificial layer 25 is still present in the partially fabricated IMOD display element formed at block 88, the movable reflective layer 14 is typically not movable at this stage. A partially fabricated IMOD display element that contains a sacrificial layer 25 also may be referred to herein as an “unreleased” IMOD.

The process 80 continues at block 90 with the formation of a cavity 19. The cavity 19 may be formed by exposing the sacrificial material 25 (deposited at block 84) to an etchant. For example, an etchable sacrificial material such as Mo or amorphous Si may be removed by dry chemical etching by exposing the sacrificial layer 25 to a gaseous or vaporous etchant, such as vapors derived from solid XeF₂ for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD display element may be referred to herein as a “released” IMOD.

In some implementations, the packaging of an EMS component or device, such as an IMOD-based display, can include a backplate (alternatively referred to as a backplane, back glass or recessed glass) which can be configured to protect the EMS components from damage (such as from mechanical interference or potentially damaging substances). The backplate also can provide structural support for a wide range of components, including but not limited to driver circuitry, processors, memory, interconnect arrays, vapor barriers, product housing, and the like. In some implementations, the use of a backplate can facilitate integration of components and thereby reduce the volume, weight, and/or manufacturing costs of a portable electronic device.

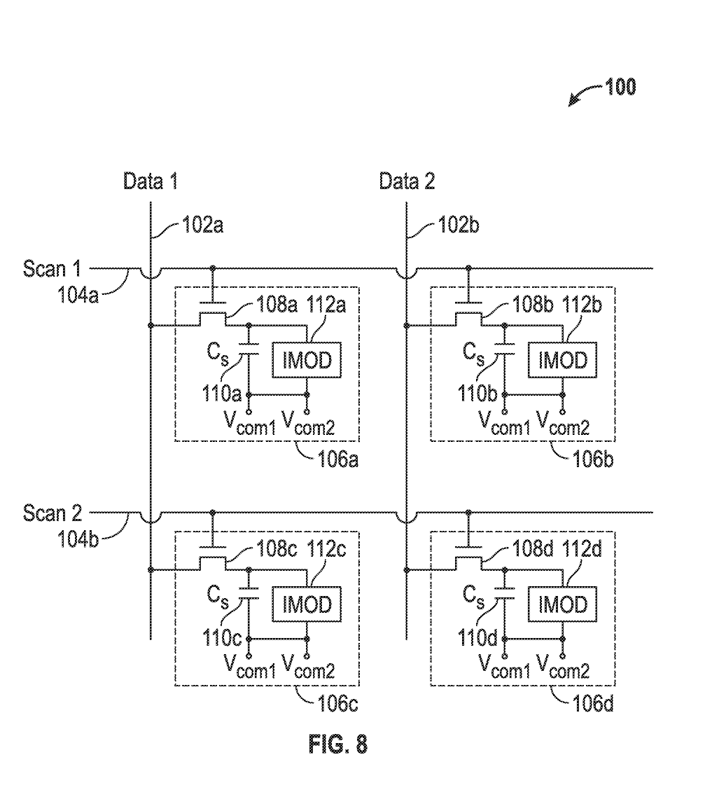

FIG. 8 shows a circuit diagram for one example of an active-matrix IMOD array 100. The illustrated IMOD array 100 includes a first data line 102a, a second data line 102b, a first scan line 104a, a second scan line 104b, a first pixel 106a, a second pixel 106b, a third pixel 106c and a fourth pixel 106d. It is understood that pixels 106a, 106, 106c, and 106d may also represent sub-pixels. Although the IMOD array 100 is illustrated as including four pixels 106 for clarity of the illustration, implementations of the IMOD array 100 can include additional pixels, including, for example, pixels of different colors and/or hundreds or thousands, or even millions, of pixels.

In the example illustrated in FIG. 8, each of the first to fourth pixels 106 includes a thin-film transistor (TFT) 108, a storage capacitor 110 and an IMOD element 112. For example, the first pixel 106a includes a first TFT 108a, a first storage capacitor 110a and a first IMOD element 112a. Similarly, the second pixel 106b includes a second TFT 108b, a second storage capacitor 110b and a second IMOD element 112b. Likewise, the third pixel 106c includes a third TFT 108c, a third storage capacitor 110c and a third IMOD element 112c. Furthermore, the fourth pixel 106d includes a fourth TFT 108d, a fourth storage capacitor 110d and a fourth IMOD element 112d.

In this implementation, the first TFT 108a includes a source electrically coupled to the first data line 102a, a gate electrically coupled to the first scan line 104a and a drain electrically coupled to a first plate of the first storage capacitor 110a and to a first electrode of the first IMOD element 112a. The second TFT 108b includes a source electrically coupled to the second data line 102b, a gate electrically coupled to the first scan line 104a and a drain electrically coupled to a first plate of the second storage capacitor 110b and to a first electrode of the second IMOD element 112b. The third TFT 108c includes a source electrically coupled to the first data line 102a, a gate electrically coupled to the second scan line 104b and a drain electrically coupled to a first plate of the third storage capacitor 110c and to a first electrode of the third IMOD element 112c. The fourth TFT 108d includes a source electrically coupled to the second data line 102b, a gate electrically coupled to the second scan line 104b and a drain electrically coupled to a first plate of the fourth storage capacitor 110d and to a first electrode of the fourth IMOD element 112d.

In the implementation schematically illustrated in FIG. 8, the first to fourth storage capacitors 110a, 110b, 110c and 110d each include a second plate or layer electrically connected to a first common voltage reference W_{COM1}, which can be, for example, a ground voltage. Additionally, the first to fourth IMOD elements 112a, 112b, 112c and 112d are each electrically coupled to a second common voltage reference V_{COM2}, which can be, for example, a ground voltage. In some implementations, a second electrode of each of the first to fourth IMOD elements 112a, 112b, 112c and 112d is electrically coupled to the second common voltage reference V_{COM2}. However, other implementations are possible. For example, the second ends of the first and second capacitors 110a and 110b can be electrically connected to the first common voltage reference and the second ends of the third and fourth capacitors 110c and 110d can be electrically connected to the second common voltage reference or a third common voltage reference. Additionally, the second electrodes of the first and second IMODs 112a and 112b can be electrically connected to the second common voltage reference and the second electrodes of the third and fourth IMODs 112c and 112d can be electrically connected to a third or fourth common voltage reference. In some implementations, the first electrode of each of the first to fourth IMOD elements 112a, 112b, 112c and 112d is a movable electrode and the second electrode of each of the first to fourth IMOD elements 112a, 112b, 112c and 112d is a stationary electrode.

In some implementations, the storage capacitors 110a, 110b, 110c and 110d illustrated in FIG. 8 can have a capacitance selected to be in the range of about 10 fF to about 1,000 fF, for example, about 60 fF. The capacitance of the storage capacitors 110a, 110b, 110c and 110d also can be selected relative to the capacitance of the IMOD elements 112a, 112b, 112c and 112d. For example, in some implementations, each storage capacitor has a capacitance that is about 1 times to about 3 times the capacitance of an associated IMOD element when the IMOD element is in an unactuated or undriven state. A person having ordinary skill in the art will readily understand that capacitance values can depend on many factors, such as air gap, pixel size, drive voltage requirement, power consumption, etc.

The first and second data lines 102a and 102b and the first and second scan lines 104a and 104b can be used to write image data to the IMOD array 100 of FIG. 8. For example, a driver circuit can provide enable signals to turn on a switch, such as TFTs 108a, 108b, 108c, and 108d. The enable signal can be provided on the first scan line 104a to address a first row of the IMOD array 100 associated with the first and second pixels 106a and 106b. The enable signal can also be provided on the second scan line 104b can be used to address a second row of the IMOD array 100 associated with the third and fourth pixels 106c and 106d. Additionally, the voltage provided to the first and second data lines 102a and 102b can be controlled so as to set the state of the IMOD elements 112 in the selected row. For example, when addressing a given row, pixels 106 in the addressed row that are to be actuated can be exposed to a voltage difference between the data line and the common voltage references V_{COM1} and V_{COM2} suitable for actuation, and pixels 106 that are to be relaxed (or unactuated) can be exposed to a voltage difference between the data line and the common voltage references V_{COM1} and V_{COM2} suitable to cause the mechanical layer or movable element of the IMOD elements 112 to be moved to a relaxed state. In some implementations, the actuation voltage is in the range of about 10 V to about 16 V, for example, about 12 V, and the relaxation voltage is in the range of about 0 V to about 8 V, for example, about 0 V or 1 V.

Equation 1 provides the drive or actuation voltage required to stably drive a movable element of an IMOD element 112 having an associated storage capacitor. The drive voltage, V_{drive}, is determined by balancing the mechanical forces present on the movable element with the electrical forces present. In Equation 1, Vₚᵢ is the pull-in voltage of the movable element, C_{off} is the capacitance of the movable element in the unactuated state, and C_{storage} is the capacitance of the storage capacitor. A person having ordinary skill in the art will readily appreciate that Equation 1 can be manipulated to determine the required size of the storage capacitor to provide enough charge such that when the movable element is driven to a certain voltage it will snap or move to the actuated state.

$${V}_{drive} = {V}_{pi} \sqrt{1 + \frac{{C}_{off}}{{C}_{storage}}} \qquad Equation 1$$

Still referring to FIG. 8, the inclusion of the first to fourth storage capacitors 110a, 110b, 110c and 110d can increase the amount of charge stored for a given amount of voltage across each IMOD element 112. For example, the amount of charge stored on each of the IMOD elements 112a, 112b, 112c and 112d can be equal to about V_{IMOD}*(C_{IMOD}+C_{storage}), where V_{IMOD} is the voltage difference between the first and second electrodes of the IMOD element 112, C_{IMOD} is the capacitance of the IMOD element 112 when the IMOD element 112 is in an unactuated or undriven state which can be assumed to be constant during the time that a pulse is applied to charge both the IMOD element 112 and the storage capacitor 110, and C_{storage} is the capacitance of the storage capacitor 110. Including the storage capacitors 110 can increase pixel charge storage and can reduce the impacts of pixel current leakage. For example, charge leakage, such as leakage associated with channel leakage of a thin-film transistor (TFT), can cause the voltage of a pixel 106 to change over time and can lead to a pixel 106 changing state if it is not refreshed at a sufficiently fast rate or if the pixel 106 does not have a sufficient amount of stored charge.

Accordingly, the first to fourth storage capacitors 110a, 110b, 110c and 110d of FIG. 8 can help prevent pixel leakage from changing the voltage across the electrodes of the first to fourth IMOD elements 112a, 112b, 112c and 112d over time, thereby improving image refresh rate and reducing drive voltage and power consumption of the pixel array 100. In this way, the image refresh rate would be improved because the image would require less refresh for a static image because the drive voltage would be maintained. As discussed below, in some implementations, the integrated storage capacitors 110a, 110b, 110c and 110d can be formed from conductive layers of the movable elements of the IMOD elements 112a, 112b, 112c and 112d. Using layers of the movable elements of the IMOD elements 112a, 112b, 112c and 112d to form the storage capacitors 110a, 110b, 110c and 110d in all or part can help integrate the design of the pixel array 100, thereby reducing the area (or footprint) of the array when compared to designs in which optical mask structures and storage capacitors would require separate real estate or space. Although the pixel array 100 illustrates one configuration suitable for using the storage capacitors 110a, 110b, 110c and 110d, integrated storage capacitors can be used in any suitable pixel array, including, for example, other implementations of active or analog IMOD arrays.

As discussed above, in some implementations an IMOD device can include a movable element or movable reflective layer including a reflective sub-layer, which can include a conductive material, and a conductive layer. The movable element can be configured to move relative to a substrate structure and/or an optical stack. In some implementations, the reflective sub-layer can be electrically isolated from the conductive layer by a dielectric support layer, or some other spacer layer. In this way, the reflective sub-layer and the conductive layer can form an integrated storage capacitor. Such an IMOD device can be included in an active-matrix pixel array, and the storage capacitor can be used to improve the performance of the active-matrix pixel array. For example, the storage capacitor can improve image refresh rate of the array and/or reduce drive voltage or power consumption of the array. Further, using layers of a movable element to form the storage capacitor can improve the integration of the pixel array, thereby reducing a footprint of the pixel array.

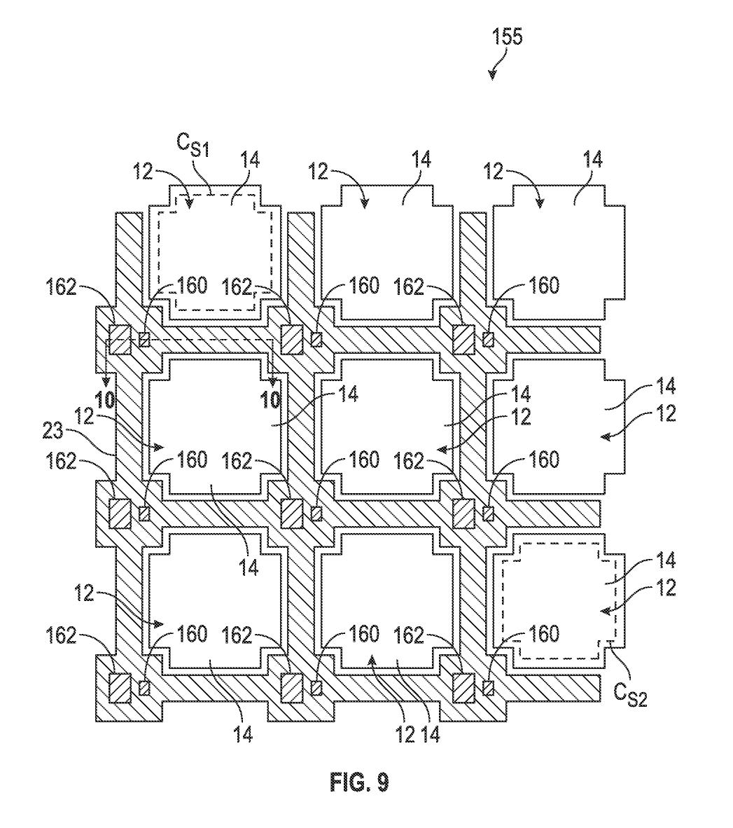

FIG. 9 shows a schematic plan view of one example of an active-matrix array 155 of display elements 12. In some implementations, the display elements or pixels 12 can include IMOD display elements each having a movable element 14 including a first conductive layer, a second conductive layer, and a dielectric support layer disposed therebetween. In some implementations, the first conductive layer can include a reflective layer and the movable element can move relative to a substrate structure and/or optical stack. The active-matrix array 155 also includes thin-film transistors (TFTs), schematically shown as TFT 162, and vias 160. The array 155 further includes a multi-layer optical mask structure 23 disposed at least partially between adjacent display elements 12.

Although not illustrated in FIG. 9 for clarity, the array 155 can include other structures. Also, the illustrated display elements 12 have been arranged in an array, and can be representative of a much larger array of display elements similarly configured. Each of the display elements 12 in this example are associated with a TFT 162 and a via 160, which can be used for electrically connecting the TFT 162 to an electrode associated with the display element 12.

The multi-layer movable elements 14 can be utilized to form storage capacitors for each of the display elements 12 of the array 155. For example, storage capacitors can be formed in regions of the array 155 in which the first and second conductive layers of the movable elements 14 overlap. For example, in regions in which each of these layers have been provided, the first and second conductive layers can operate as electrodes, plates or layers of a storage capacitor, and the dielectric support layer can electrically isolate these electrodes, plates or layers from one another. For example, a first storage capacitor C_{S1} has been illustrated and is associated with the upper-left display element 12 of the array 155, and a second storage capacitor C_{S2} has been illustrated and is associated with the bottom-right display element 12 of the array 155. As discussed below, each storage capacitor formed by movable element 14 can be electrically coupled to at least one switch, for example, a TFT, configured to control a flow of charge between a source and the associated display element 12.

FIGS. 10A-10P show examples of cross-sectional schematic illustrations of various stages in a method of making the active-matrix array 155 of FIG. 9 taken along the line 10-10. While particular parts and steps are described as suitable for fabricating certain implementations of an array, for other implementations, different parts and steps, and materials can be used, or parts can be modified, omitted, or added.

In FIGS. 10A and 10B, an optical mask structure 23 has been provided on a substrate structure or substrate 20. The substrate 20 can include glass, plastic or any transparent polymeric material which permits light to pass through the substrate 20. In “inverse” or “reverse” IMOD configurations, the substrate 20 may also be opaque. The illustrated optical mask structure 23 is a multi-layer structure including a first conductive layer 23a, a spacer layer 23b and a second conductive layer 23c. The first conductive layer 23a, the second conductive layer 23c and the spacer layer 23b can include any suitable materials. At least one layer of the optical mask structure 23 can be configured to absorb ambient or stray light in optically inactive regions of the array. However, each layer of the optical mask structure 23 need not absorb light.

In some implementations, the first conductive layer 23a can include a partially reflective, partially transmissive, and partially absorptive material, for example, MoCr, and can have a thickness in the range of about 30-80 Å. The spacer layer 23b can include a non-conductive or dielectric material, for example, SiO₂, having a thickness in the range of about 500-1000 Å. The second conductive layer 23c can include a reflective material, for example, Al or Mo, and can have a thickness in the range of about 500-6000 Å. In some implementations, the reflective second conductive layer 23c has a higher reflectance than the first conductive layer 23a and the second conductive layer 23c has an absorption coefficient that is lower than the first conductive layer 23a.

FIG. 10C illustrates providing a spacer or buffer layer 35. The buffer layer 35 can include, for example, SiO₂, SiN, SiON, tetraethyl orthosilicate (TEOS), and/or any other suitable dielectric material(s). In some implementations, the thickness of the buffer layer 35 is in the range of about 1,000-10,000 Å, however, the buffer layer 35 can have a variety of thicknesses depending on desired optical properties. A portion of the buffer layer 35 can be removed over the first conductive layer 23a (“over” here referring to the side of the first conductive layer 23a opposite the substrate 20) so as to permit the formation of a via for electrically connecting the optical mask structure 23 to a TFT and an electrode of a display element, as will be described in further detail below. For example, the buffer layer 35 has been patterned, removing a portion of the buffer layer 35, to form an opening 172 through which a subsequently deposited conductor can contact the second conductive layer 23c. In such an implementation, conductive layers in the optical mask structure may serve as a bus for signals routed to the TFT. In this way, the optical mask structure 23 can be electrically connected to another structure disposed over the optical mask structure. For example, the optical mask structure 23 can be electrically coupled to a TFT and an electrode of a movable element.

In FIG. 10D, an active layer 131 has been provided and patterned on the buffer layer 35. In some implementations, the active layer 131 includes silicon (Si) and/or any other semiconductor material suitable for forming a channel region of a TFT device. The active layer 131 can be doped using n-type or p-type dopants, including, for example, boron (B), phosphorous (P), or arsenic (As) to achieve the desired channel conductivity. The doping can be accomplished using any suitable process, including, for example, ion implantation.

In FIG. 10E, a gate dielectric layer 132 has been provided and patterned over the device of FIG. 10D. In FIG. 10F, a gate layer 133 has been provided over the gate dielectric layer 132 to form a gate structure of the TFT 162. In some implementations, the gate dielectric layer 132 and the gate layer 133 can include silicon dioxide (SiO₂) and for example, molybdenum, respectively. As illustrated in FIGS. 10E and 10F, the gate dielectric layer 132 can be patterned such that the opening 172 extends through both the buffer layer 35 and the gate dielectric layer 132 so as to allow a subsequently deposited layer to physically and electrically contact the second conductive layer 23c of the optical mask structure 23.

In FIG. 10G, a spacer dielectric layer 134 is formed over the gate layer 133. The spacer dielectric layer 134 can be used to electrically isolate the gate layer 133 formed in FIG. 10F from subsequently deposited conductive layers and/or to protect the gate layer 133 during processing. In some implementations, the spacer dielectric layer 134 includes silicon dioxide (SiO₂). The spacer dielectric layer 134 and gate dielectric layer 132 can be patterned to include openings, such as openings that can be used to contact the active layer 131. Additionally, the spacer dielectric layer 134 can be patterned such that the opening 172 also extends through the spacer dielectric layer 134.

FIG. 10H illustrates forming a source/drain conductive layer or transistor contact layer 135 over the spacer dielectric layer 134. The source/drain conductive layer 135 can include any suitable conductor, such as aluminum (Al), and can be patterned to form a desired metal connectivity for the sources and drains of the TFT 162. In the illustrated configuration, the source/drain conductive layer 135 has been formed over the opening 172 of FIG. 10G to form a via 160. The via 160 can be used to provide electrical connectivity between the TFT 162, the optical mask structure 23, and an electrode of a subsequently deposited movable element. As discussed below, the movable element can include a storage capacitor C_{S1}. In this way, the optical mask structure 23, TFT 162, and storage capacitor C_{S1} of the movable element can be electrically connected. In the illustrated configuration, the via 160 is used to electrically connect the source/drain conductive layer 135 to the second conductive layer 23c of the optical mask structure 23. However, as discussed below, the via 160 can be configured in other ways, such as to provide a connection between the source/drain conductive layer 135 and the first conductive layer 23a.

In FIG. 10I a planarization layer 136 has been formed over the spacer dielectric layer 134 and the source/drain conductive layer 135. The planarization layer 136 can be used as a surface over which a display element can be formed, and in some implementations can include silicon dioxide (SiO₂).

As illustrated in FIG. 10J, an optical stack 16 can be formed over the planarization layer 136. In some implementations, the optical stack 16 can include a stationary electrode 116a, a first dielectric layer 116b and a second dielectric layer 116c. As illustrated, the stationary electrode 116a can be patterned to provide electrical isolation between pixels or display elements of the array. In some implementations, the stationary electrode 116a can include an optically partially reflective, partially transmissive, and partially absorptive electrical conductor such as molybdenum-chromium (MoCr). In some implementations, the first dielectric layer 116b can include silicon dioxide (SiO₂) and/or silicon oxynitride (SiON), and the second dielectric layer 116c can include aluminum trioxide (Al₂O₃). Although the optical stack 16 includes two dielectric layers in the illustrated configuration, in some implementations the optical stack 16 can include more or fewer dielectric layers and/or can be modified to include other layers (for example, one or more non-dielectric layers). Additionally, although the first and second dielectric layer 116b and 116c are shown as having the same pattern, other configurations are possible.

Although line 10-10 in FIG. 9 does not extend through the display element 12, the formation of the display element 12 adjacent to the cross-section through line 10-10 of FIG. 9 will now be described with reference to FIGS. 10L-10P. Thus, it will be readily apparent to those skilled in the art that although these figures are characterized as cross-sectional views through the array 155, portions of the array 155, including, for example, portions of the display element 12, that are not part of the cross-section through line 10-10 are illustrated to show the relationship between the TFT 162, optical mask structure 23, and display element 12. Further, for the sake of convenience, the TFT 162 and other components are not illustrated to scale. For example, the TFT 162 is shown larger relative to the width of the display element 162 in order to properly illustrate the TFT 162 and the formation of the array 155.

FIG. 10K illustrates providing and patterning a sacrificial layer 25 over the optical stack 16. The sacrificial layer 25 can subsequently be removed or released to form a gap or cavity in the display element. The formation of the sacrificial layer 25 over the optical stack 16 can include a deposition step, as described above. Additionally, the sacrificial layer 25 can be selected to include more than one layer, or include a layer of varying thickness, to aid in the formation of a display device having a multitude of resonant optical gaps between different display elements. For an array of IMOD display elements, each gap size can represent a different reflected color.

FIG. 10L also illustrates providing and patterning a support layer over the sacrificial layer 25 to form support posts 18. The support posts 18 can be formed from, for example, silicon dioxide (SiO₂) and/or silicon oxynitride (SiON), and the support layer may be patterned to form the support posts 18 by a variety of techniques, such as using a dry etch including carbon tetraflouride (CF₄) and/or oxygen (O₂). As illustrated in FIG. 10L, in some implementations the support posts 18 can be positioned at pixel corners.

FIG. 10M illustrates providing and patterning a movable element or mechanical layer 14 of the display element over the sacrificial layer 25 as well as opening a via 174 to stationary electrode 116a. As shown, the movable element 14 includes a first conductive layer 14a, which can be reflective, a second conductive layer 14c, and a dielectric support layer 14b disposed therebetween. Overlapping portions of the first and second conductive layers 14a and 14c can be used to form the storage capacitor C_{S1}. For example, the first and second conductive layers 14a and 14c can operate as plates or electrodes of the storage capacitor C_{S1}, and the dielectric support layer 14b can electrically isolate the plates or electrodes of the storage capacitor C_{S1}. As illustrated, first conductive layer 14a extends beyond the other layers on one side of the IMOD display element to allow for electrical connection or routing of signals to the first conductive layer 14a. For example, the first conductive layer may be grounded or may be connected to a voltage (such as Vcom1 shown in FIG. 8). In such an implementation, one of the electrodes of the storage capacitor and one of the electrodes of the IMOD display element are the same layer, namely, here, first conductive layer 14a. On the other side of the IMOD display element, conductive layer 14c extends beyond the other layers to allow for connection to the drain of the TFT 162 and to the stationary electrode 116a.

The first and second conductive layers 14a and 14c can be electrically isolated from one another by the dielectric support layer 14b and electrically connected to the desired electrical potentials to operate the movable element 14 as a storage capacitor C_{S1}. For example, the second conductive layer 14c can be electrically connected to a reference voltage such as ground through the TFT 162 and the first conductive layer 14a can be electrically connected to a driver. In some implementations, the dielectric support layer 14b can have an electrical thickness of between 30 nm and 70 nm, for example, 50 nm. In some implementations, the dielectric support layer 14b can include silicon oxy-nitride and have a physical thickness of between 20 nm and 4000 nm, for example, between 200 nm and 250 nm. The electrical thickness, and resultant physical thickness, of the dielectric support layer 14b can be selected such that the capacitance of the storage capacitor C_{S1} is sufficient to drive the movable element 14 when required.

FIG. 10O illustrates the active matrix array after an opening 191 has been formed through the post 18, stationary electrode 116a, first dielectric layer 116b, second dielectric layer 116c, and planarization layer 136. Such patterning exposes the contact layer 135 and allows electrical coupling to the contact layer 135 via the opening 191.

FIG. 10P illustrates the display element 12 after deposition and patterning of a conductive layer 199 and removal of the sacrificial layer 25 of FIG. 10M to form a gap 19. As shown in FIG. 10P, the conductive layer 199 electrically connects the second conductive layer 14c of the movable element 14 and the stationary electrode 116a to the TFT 162. In this way, one terminal of the storage capacitor C_{S1}, for example, the second conductive layer 14c of the movable element 14, can be electrically connected to the TFT 162. The sacrificial layer 25 may be removed at this point using a variety of methods, as described earlier. With the sacrificial layer 25 removed, the movable element 14 may move through the gap 19 toward the stationary electrode 116a between at least an actuated position and a relaxed position when a voltage is applied between the stationary electrode 116a and the movable element 14.

The display element illustrated in FIG. 10P can be used in a high fill-factor pixel array. As illustrated, the movable element 14 is configured to move in response to a voltage applied between the stationary electrode 116a and, for example, the first conductive layer 14a. While FIG. 10P is illustrated as one implementation of the circuit diagram of FIG. 8, it is understood that the TFT 162, stationary electrode 116a, first conductive layer 14a and second conductive layer 14c may be interconnected in different ways to implement the circuit show in FIG. 8.

With reference to FIGS. 10O and 10P, each pixel or display element 12 of the pixel array 155 can include a storage capacitor Cₛ formed from the movable element 14, thereby improving the integration of the design. Additionally, each TFT 162 has been formed over the optical mask structure 23 and an integrated via 160 has been used to provide electrical connectivity between the storage capacitor Cₛ and TFT 162.

By providing a storage capacitor for each display element in the array, performance can be improved without impacting a fill-factor of the array. For example, as discussed below, providing a storage capacitor can allow the movable element 14 to move further toward the stationary electrode 116a than implementations that do not include a storage capacitor because the driving voltage can be maintained at a level sufficient to move the movable element 14 despite the increase in capacitance between the movable element 14 and the stationary electrode 116a as the movable element 14 nears the stationary electrode 116a.

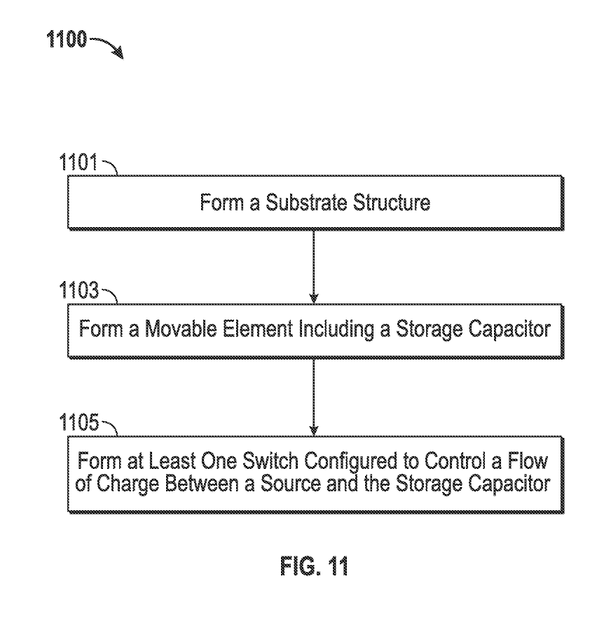

FIG. 11 shows an example of a flow diagram illustrating a method 1100 of forming a device. Block 1101 of the example method 1100 includes forming a substrate structure. In some implementations, the substrate structure can include glass, plastic or any transparent polymeric material which permits light to pass through the substrate. In some “inverse” or “reverse” IMOD architectures, the substrate structure need not be transparent and may be opaque. In some implementations, the substrate structure can be configured to the substrate 20 described above with reference to FIGS. 10A-10P.

The example method 1100 also includes forming a movable element including a storage capacitor, as shown by block 1103. The movable element can be configured to move in a direction perpendicular to the substrate structure. In some implementations, the movable element can be configured similar to the movable element 14 described above with reference to FIG. 10P and can include a first conductive layer and a second conductive layer that form the storage capacitor. For example, the movable element can include a dielectric support layer disposed between the first and second conductive layers. The dielectric support layer can serve a mechanical function for the movable element 14 while also serving an electrical function as a dielectric between the first and second conductive layers.

The example method 1100 also includes forming at least one switch, as shown by block 1105. In some implementations, the at least one switch can be configured to control a flow of charge between a source and the storage capacitor. Forming the at least one switch can include forming a thin-film transistor (TFT) similar to the TFT structures 162 described above.

In some implementations, the example method 1100 can include forming an optical stack between the movable element and the substrate structure. The optical stack can include a stationary electrode and one or more dielectric layers similar to the stationary electrode 116a and first and second dielectric layers 116b, 116c described above. Many additional steps may be employed before, in the middle of, or after the illustrated sequence, but such steps are omitted here for clarity of the description.

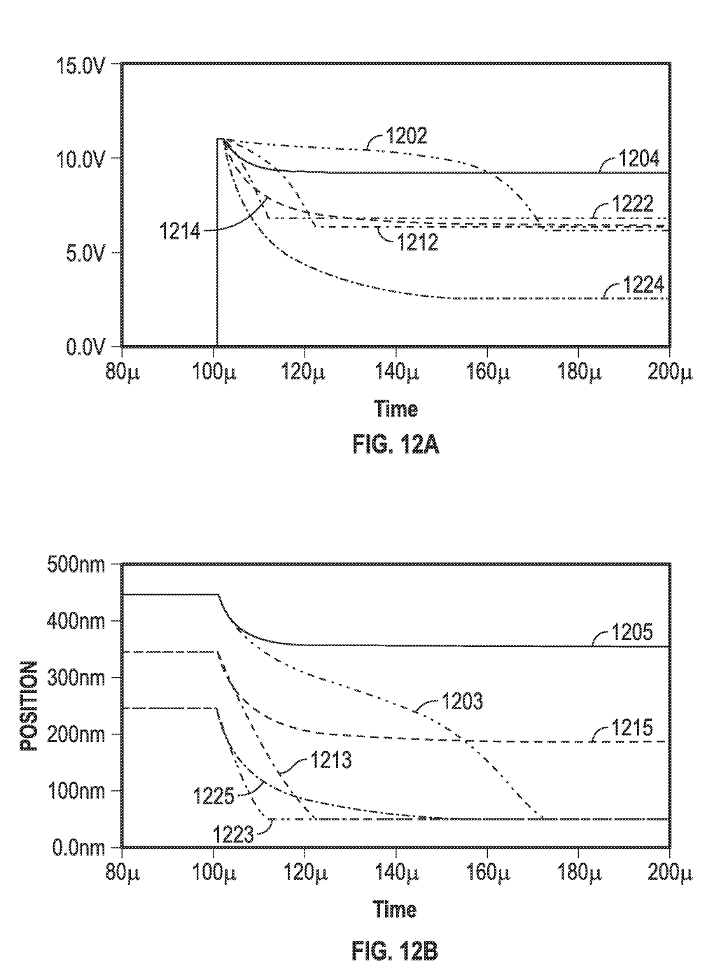

FIG. 12A shows an example of voltage over time for movable elements including a storage capacitor and for movable elements without a storage capacitor. As discussed above, an IMOD display element can reflect one or more wavelengths of visible light by changing the position of the movable element relative to an optical stack and/or by changing the thickness of an optical resonant cavity defined therebetween. In some implementations, the position of the spectral band reflected by a display element can be adjusted by applying a voltage between the movable element and a stationary electrode to drive the movable element relative to the stationary electrode. Curves 1204, 1214, and 1224 of FIG. 12A show plots of voltage over time for display elements without a storage capacitor that are configured to reflect green light, blue light, and red light, respectively. Curves 1202, 1212, and 1222 of FIG. 12A show plots of voltage over time for display elements including a storage capacitor that are configured to reflect green light, blue light, and red light, respectively. As shown by comparing curves 1204, 1214, and 1224 to curves 1202, 1212, and 1222, the voltage between the movable elements and stationary electrodes for the display elements without a storage capacitor decreases more quickly over time as compared to the display elements including storage capacitors because the capacitance between a movable element and a stationary electrodes increases when the movable element is driven towards the stationary electrode.

FIG. 12B shows an example of position over time for the movable elements of FIG. 12A with the position measured relative to a stationary electrode. In this example, curves 1203, 1213, and 1223 show plots of the position of a movable element including a storage capacitor for display elements that are configured to reflect green light, blue light, and red light, respectively. Curves, 1205, 1215, and 1225 show plots of the position of a movable element without a storage capacitor for display elements that are configured to reflect green light, blue light, and red light, respectively. By comparing curves 1203, 1213, and 1223 to curves 1205, 1215, and 1225 it can be seen that a movable element including a storage capacitor can move nearer to an associated stationary electrode because the voltage between the movable element and the stationary electrode can be maintained sufficiently high to drive the movable element as the capacitance between the movable element and the stationary electrode increases. Accordingly, FIGS. 12A and 12B demonstrate that a movable element incorporating a storage capacitor can be driven through a greater range of stable movement relative to a stationary electrode than a display element without a storage capacitor.

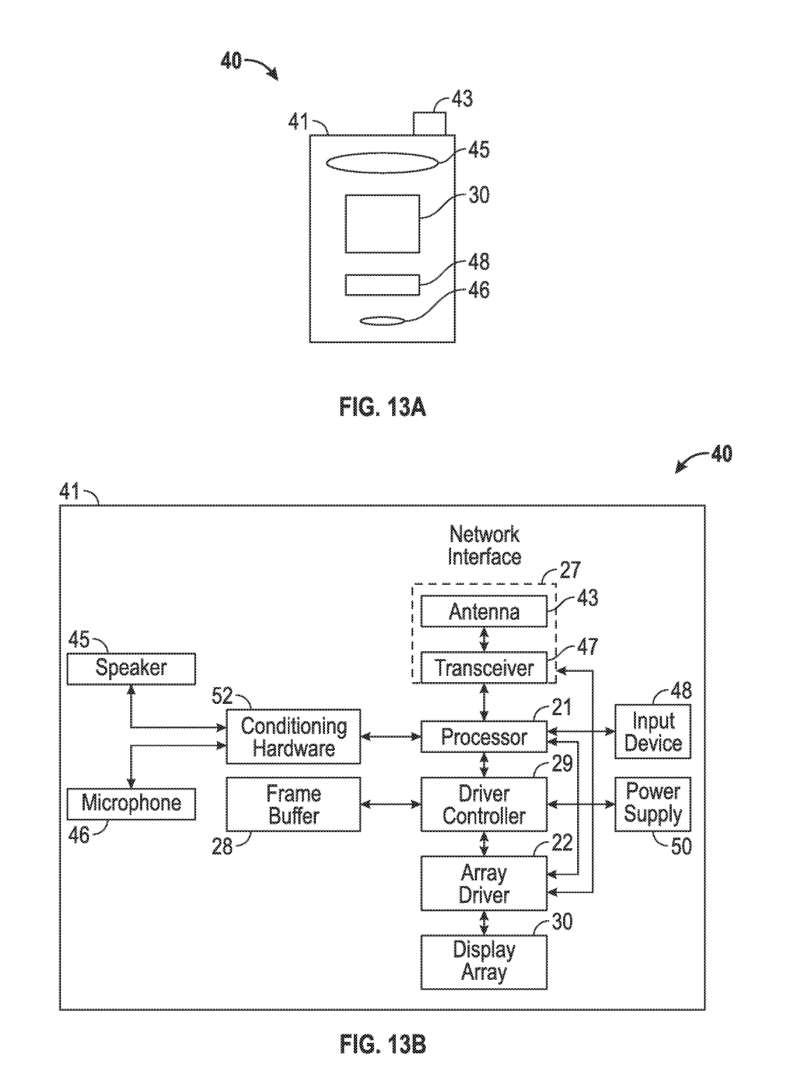

FIGS. 13A and 13B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display with an integrated storage capacitor, as described herein.

The components of the display device 40 are schematically illustrated in FIG. 13A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 13A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22. In some implementations, the driver controller 29 (or a driver circuit) can be configured to send at least one signal to a movable element 14 (e.g., FIGS. 1 and 10N). In some implementations the driver controller 29 (or a driver circuit) can be configured to send a signal to enable at least one switch. Examples of such movable element include any of the implementations of movable elements described and/or illustrated herein. In some implementations the at least one switch can be, for example, a thin-film transistor 108 as illustrated in FIG. 8, or another type of switch.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22, and may one or both, or both combined, may be referred to as a driver circuit. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device, comprising:
a substrate structure having a stationary electrode;
a movable element configured to move in a direction generally perpendicular to the substrate, the movable element including a first conductive layer and a second conductive layer, the first and second conductive layers forming a storage capacitor; and
at least one switch configured to control a flow of charge between a source and the storage capacitor.

2. The device of claim 1, wherein the device is configured such that the storage capacitor is electrically coupled to the movable element and provides voltage to the movable element at least when the movable element is actuated.

3. The device of claim 2, further comprising an optical stack disposed between the movable element and the substrate structure, the optical stack including a partially reflective and partially transmissive layer.

4. The device of claim 3, wherein the optical stack and the movable element form an interferometric modulator (IMOD) display element.

5. The device of claim 1, wherein the at least one switch includes a thin-film transistor.

6. The device of claim 1, wherein the movable element includes a dielectric layer disposed between the first conductive layer and the second conductive layer.

7. The device of claim 6, wherein the dielectric layer includes silicon oxy-nitride.

8. The device of claim 7, wherein the dielectric layer has a thickness dimension between 20 nm and 4000 nm.

9. The device of claim 1, wherein the first conductive layer is connected to an electrical ground.

10. The device of claim 1, wherein the at least one switch includes a thin-film transistor.

11. The device of claim 10, wherein the second conductive layer is connected to a drain of the thin-film transistor and the stationary electrode.

12. The device of claim 1, wherein the movable element is configured to move in response to a voltage difference applied between the stationary electrode and the first conductive layer.

13. The device of claim 1, further comprising:
a display, wherein the display includes the movable element;
a processor that is configured to communicate with the display, the processor being configured to process image data; and
a memory device that is configured to communicate with the processor.

14. The device of claim 13, further comprising a driver circuit configured to send at least one signal to the movable element and to send a signal to enable the at least one switch.

15. The device of claim 14, further comprising a controller configured to send at least a portion of the image data to the driver circuit.

16. The device of claim 15, further comprising an image source module configured to send the image data to the processor.

17. The device of claim 13, further comprising an input device configured to receive input data and to communicate the input data to the processor.

18. A method of forming a device, the method comprising:
forming a substrate structure;
forming a movable element configured to move in a direction generally perpendicular to the substrate structure, the movable element including a first conductive layer and a second conductive layer, the first and second conductive layers forming a storage capacitor; and
forming at least one switch, the switch configured to control a flow of charge between a source and the storage capacitor.

19. The method of claim 18, further comprising forming an optical stack, the optical stack being disposed between the movable element and the substrate structure.

20. The method of claim 18, wherein forming the at least one switch includes forming a thin-film transistor.

21. A display device comprising:
an electromechanical system, including
a substrate structure, and
a display element including a movable means for storing charge and for reflecting light, the light reflecting charge storing means being configured to be driven in a direction generally perpendicular to the substrate structure to at least a first actuated position and a relaxed position, and the light reflecting charge storing means further configured to provide voltage to at least one a conductive layer of the movable means while the movable means is being actuated; and
means for controlling a flow of charge between a source and the storage capacitor.

22. The device of claim 21, wherein the movable means for storing charge and for reflecting light includes a first conductive layer, a second conductive layer, and a dielectric layer between the first conductive layer and the second conductive layer, and wherein the first and second conductive layers and the dielectric layer form a movable storage capacitor.

23. The device of claim 21, wherein the charge controlling means includes at least one switch.

24. The device of claim 23, wherein the at least one switch includes a thin-film transistor.
